(19) United States
(12) Patent Application Publication
(10) Pub. No.: US 2025/0224669 A1
(43) Pub. Date: Jul. 10, 2025

(54) METHOD OF FORMING PATTERNS AND PHOTORESIST FILM

(71) Applicant: SAMSUNG SDI CO., LTD., Yongin-si (KR)

(72) Inventors: Changsoo WOO, Suwon-si (KR); Kyungsoo MOON, Suwon-si (KR); Minyoung LEE, Suwon-si (KR); Seung-Wook SHIN, Suwon-si (KR)

(21) Appl. No.: 18/948,220

(22) Filed: Nov. 14, 2024

(30) Foreign Application Priority Data
Jan. 4, 2024 (KR) 10-2024-0001648

(51) Int. Cl. G03F 7/004; C07F 7/22; G03F 7/16; H01L 21/027

(52) U.S. Cl. CPC G03F 7/0042; C07F 7/2224; H01L 21/0274; G03F 7/167

(57) ABSTRACT

Disclosed is a method of forming patterns and a photoresist film, the method of forming patterns including coating a semiconductor photoresist composition including an organic tin compound on a substrate; drying and heating to form a photoresist film; and exposing and developing the photoresist film, wherein the organic tin compound has at least one organic ligand including a Sn-C bond and at least one organic carbonyloxy group, and the photoresist film includes a compound represented by (R¹Sn)ₓO_{y}(OAR²)_{z} before or after exposure, and the photoresist film including a compound represented by (R¹Sn)ₓO_{y}(OAR²)_{z}.

### CROSS-REFERENCE TO RELATED APPLICATION

The present application claims priority to and the benefit of Korean Patent Application No. 10-2024-0001648, filed on Jan. 4, 2024, in the Korean Intellectual Property Office the entire content of which is hereby incorporated by reference.

### BACKGROUND

### 1. Field

Embodiments of this disclosure relate to methods of forming patterns and photoresist films used to form the patterns.

### 2. Description of the Related Art

EUV (extreme ultraviolet) lithography has been paid attention to as one important technology for manufacturing a next generation semiconductor device. EUV lithography is a pattern-forming technology that uses an EUV ray having a wavelength of about 13.5 nm as an exposure light source. According to the EUV lithography, an extremely fine pattern (e.g., less than or equal to about 20 nm) may be formed in an exposure process during manufacture of a semiconductor device.

Extreme ultraviolet (EUV) lithography is realized through development of compatible photoresists which can be performed at a spatial resolution of less than or equal to about 16 nm. Currently, efforts to satisfy unsuitable or insufficient specifications of traditional chemically amplified (CA) photoresists such as a resolution, a photospeed, and feature roughness (which may also be referred to as a line edge roughness or LER) for next generation devices are being made.

An intrinsic image blurring due to an acid catalyzed reaction in these polymer-type photoresists limits a resolution with respect to small feature sizes, which has been present in electron beam (e-beam) lithography for a long time. Chemically amplified (CA) photoresists are designed for high sensitivity, but because their general elemental makeups reduce light absorbance of the photoresists at a wavelength of about 13.5 nm and thus decrease their sensitivity, chemically amplified (CA) photoresists may at least partially have more difficulties under an EUV exposure.

CA photoresists may have difficulties with respect to small feature sizes due to roughness issues, and line edge roughness (LER) of CA photoresists experimentally turns out to be increased, as a photospeed is decreased at least partially due to the nature of acid catalyst processes. Accordingly, a high-performance photoresist would be beneficial for the semiconductor industry because of these defects and problems of existing CA photoresists.

In order to overcome the aforementioned drawbacks of chemically amplified (CA) organic photosensitive compositions, an inorganic photosensitive composition has been researched. Inorganic photosensitive composition are mainly used for negative tone patterning having resistance against removal by a developer composition due to chemical modification through a nonchemical amplification mechanism. Such inorganic photosensitive compositions contain an inorganic element having a higher EUV absorption rate than relevant hydrocarbons and thus may secure sensitivity through the nonchemical amplification mechanism and are less sensitive with respect to a stochastic effect and thus have low line edge roughness and a small number of defects.

Inorganic photoresists based on peroxopolyacids of tungsten mixed together with tungsten, niobium, titanium, and/or tantalum have been reported as radiation sensitive materials for patterning.

The foregoing materials are effective for patterning large pitches for a bilayer configuration as far ultraviolet (deep UV), X-ray, and electron beam sources. More recently, when cationic hafnium metal oxide sulfate (HfSOx) materials along with a peroxo complexing agent have been used to image a 15 nm half-pitch (HP) through projection EUV exposure, impressive performance has been obtained. The foregoing system exhibits the highest performance of a non-CA photoresist and has a practicable photospeed near to a suitable level for an EUV photoresist. However, the hafnium metal oxide sulfate material having the peroxo complexing agent has a few practical drawbacks. First, these materials are coated in a mixture of corrosive sulfuric acid/hydrogen peroxide and have unsuitable or insufficient shelf-life stability. Second, a structural change thereof for performance improvement as a composite mixture is not easy. Third, development should be performed in a TMAH (tetramethylammonium hydroxide) solution at an extremely high concentration of about 25 wt % and/or the like.

Recently, active research has been conducted with respect to molecules containing tin that have excellent absorption of extreme ultraviolet rays. As for an organotin polymer among them, alkyl ligands are dissociated by light absorption or secondary electrons produced thereby, and are crosslinked with adjacent chains through oxo bonds and thus enable the negative tone patterning which may not be removed by an organic developer. The foregoing organotin polymer exhibits greatly improved sensitivity as well as maintains a resolution and line edge roughness, but the patterning characteristics should be additionally improved for commercial availability.

### SUMMARY

A method of forming patterns according to some embodiment provides a pattern having improved sensitivity.

Some embodiments relate to a photoresist film provided in a pattern forming method.

A method of forming patterns according to some embodiment includes coating a semiconductor photoresist composition including an organic tin compound on a substrate; drying and heating to form a photoresist film; and exposing and developing the photoresist film, wherein the organic tin compound has at least one organic ligand including a Sn-C bond and at least one organic carbonyloxy group, and the photoresist film includes a compound represented by (R¹Sn)ₓO_{y}(OAR²)_{z} (wherein x, y, and z are each independently 0.1 to 0.9, x+y+z=1, A is a single bond (e.g., a single covalent bond) or C═O, R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and Ra is a substituted or unsubstituted C1 to C20 alkyl group), and R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) before or after exposure.

A photoresist film according to some embodiments includes a compound represented by (R¹Sn)ₓO_{y}(OAR²)_{z}.

Sensitivity can be improved by using the method of forming patterns according to some embodiments.

### BRIEF DESCRIPTION OF THE DRAWINGS

The accompanying drawings, together with the specification, illustrate embodiments of the subject matter of the present disclosure, and, together with the description, serve to explain principles of embodiments of the subject matter of the present disclosure.

FIGS. 1-5 are cross-sectional views for explaining a method of forming patterns using a semiconductor photoresist composition according to some embodiments.

### DETAILED DESCRIPTION

Hereinafter, referring to the drawings, embodiments of the present disclosure are described in more detail. In the following description of the present disclosure, well-known functions or constructions will not be described in order to clarify the subject matter of the present disclosure.

In order to clearly illustrate embodiments of the present disclosure, certain description and relationships may be omitted, and throughout the disclosure, the same or similar configuration elements are designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be enlarged for clarity. In the drawings, the thickness of a part of layers or regions, etc., may be exaggerated for clarity. It will be understood that if an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, if a definition is not otherwise provided, “an alkyl group” refers to a linear or branched aliphatic hydrocarbon group. The alkyl group may be “a saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, “aliphatic unsaturated organic group” refers to a hydrocarbon group including a bond (e.g., a covalent bond) in which a bond between a carbon atom and another carbon atom in the molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-1 propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms) functional group.

As used herein, “heteroaryl group” refers to an aryl group including at least one heteroatom selected from N, O, S, P, and Si. Two or more heteroaryl groups may be linked by a sigma bond directly, or if the heteroaryl group includes two or more rings, the two or more rings may be fused together. If the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

The organic tin compound may include at least one selected from an organic oxy group and an organic carbonyloxy group.

The organic tin compound may be represented by Chemical Formula 1.

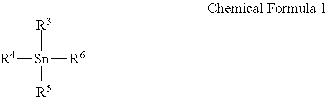

In Chemical Formula 1,
R³ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and Ra is a substituted or unsubstituted C1 to C20 alkyl group),
R⁴ to R⁶ are each independently selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, —OR^{b}, and —OC(═O)R^{c},
at least one selected from R⁴ to R⁶ is selected from —OR^{b} and —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

As an example, R⁴ to R⁶ may be selected from —OR^{b} and —OC(═O)RC.

In embodiments, the compound represented by Chemical Formula 1 includes —OR^{b} or —OC(═O)R^{c} as a ligand, so that a pattern formed using a semiconductor photoresist composition including the compound represented by Chemical Formula 1 can exhibit excellent limiting resolution.

In embodiments, the —OR^{b} or —OC(═O)R^{c} ligand can determine the solubility of the compound represented by Chemical Formula 1 in a solvent.

R³ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof,
R^{b} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{c} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R³ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{b} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{c} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

The semiconductor photoresist composition may be formed into a pattern having a high aspect ratio without collapse of the pattern. In embodiments, in order to form a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, or about 5 nm to about 20 nm, the semiconductor photoresist composition may be used for a photoresist process using light in a wavelength range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to an embodiment may be used to realize extreme ultraviolet lithography using an EUV light source that provides light having a wavelength of about 13.5 nm.

A method of forming patterns according to some embodiments includes coating a semiconductor photoresist composition including an organic tin compound on a substrate; drying and heating to form a photoresist film; and exposing and developing the photoresist film, wherein the organic tin compound has at least one organic ligand including a Sn-C bond and at least one organic carbonyloxy group, and the photoresist film includes a compound represented by (R¹Sn)ₓO_{y}(OAR²)Z (wherein x, y, and z are each independently 0.1 to 0.9, x+y+z=1, A is a single bond (e.g., a single covalent bond) or C═O, R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and Ra is a substituted or unsubstituted C1 to C20 alkyl group), and R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) before or after exposure.

As an example, the manufactured pattern may be a photoresist pattern.

The photoresist film may include an Sn—OAR² bond, an Sn—O—Sn bond, and/or an Sn—C bond.

Before exposure, a content of the compound represented by (R¹Sn)ₓO_{y}(OAR²)_{z} included in the photoresist film may be about 5 to about 95 wt % based on 100 wt % of the composition for semiconductor photoresist.

After exposure and development, a content of the compound represented by (R¹Sn)ₓO_{y}(OAR²)_{z} included in the photoresist film may be about 5 to about 95 wt % based on 100 wt % of the semiconductor photoresist composition.

As an example, R¹ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof, and
R² may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

As an example, R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof, and
R² may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

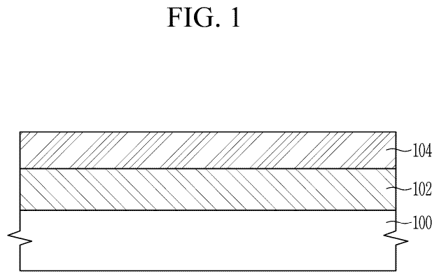

Hereinafter, a method of forming patterns using the semiconductor photoresist composition is described referring to FIGS. 1-5. FIGS. 1-5 are cross-sectional views illustrating a method of forming patterns using a semiconductor photoresist composition according to embodiments of the present disclosure.

Referring to FIG. 1, an object for etching is prepared. The object for etching may be a thin film 102 on a semiconductor substrate 100. Hereinafter, the object for etching is limited to the thin film 102, but the present disclosure is not limited thereto. A surface of the thin film 102 is washed to remove impurities and/or the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, the present disclosure is not limited thereto, and various suitable coating methods, for example a spray coating, a dip coating, a knife edge coating, a printing method, for example an inkjet printing and/or a screen printing, and/or the like may be used.

The coating process of the resist underlayer may be omitted, and hereinafter, a process including a coating of the resist underlayer is described.

The coated composition is dried and baked to form a resist underlayer 104 on the thin film 102. The baking may be performed at about 100° C. to about 500° C., for example, about 100° C. to about 300° C.

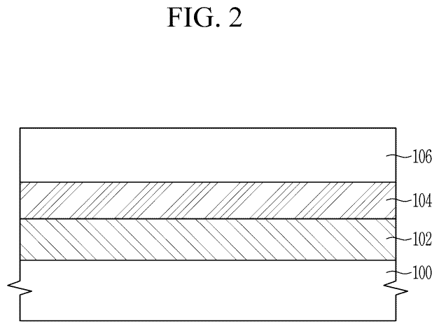

The resist underlayer 104 is between the substrate 100 and a photoresist film 106 (FIG. 2) and thus may prevent or reduce non-uniformity and improve pattern formability of a photoresist line width by avoiding or reducing scattering of a ray reflected from the interface between the substrate 100 and the photoresist film 106 or a hardmask between layers into an unintended photoresist region.

Referring to FIG. 2, the photoresist film 106 is formed by coating the semiconductor photoresist composition on the resist underlayer 104. The photoresist film 106 is obtained by coating the aforementioned semiconductor photoresist composition on the thin film 102 on the substrate 100 and then, curing it through a heat treatment.

In embodiments, the coating of the semiconductor photoresist composition includes coating the semiconductor photoresist composition on the substrate 100 on which the thin film 102 is formed by a deposition method selected from chemical vapor deposition (CVD) and physical vapor deposition (PVD) and/or a coating method selected from spin coating, slit coating, and inkjet printing, and may include drying the coated semiconductor photoresist composition to form a photoresist film 106.

The semiconductor photoresist composition may include an organic tin compound having at least one organic ligand including a Sn-C bond and at least one organic carbonyloxy group.

The semiconductor photoresist composition according to some embodiments may include the aforementioned organic tin compound and a solvent, and may further include a resin.

The solvent included in the semiconductor photoresist composition may be an organic solvent, and may be for example aromatic compounds (e.g., xylene, toluene, etc.), alcohols (e.g., 4-methyl-2-pentenol, 4-methyl-2-propanol, 1-butanol, methanol, isopropyl alcohol, 1-propanol, etc.), ethers (e.g., anisole, tetrahydrofuran, etc.), esters (n-butyl acetate, propylene glycol monomethyl ether acetate, ethyl acetate, ethyl lactate, etc.), ketones (e.g., methyl ethyl ketone, 2-heptanone, etc.), or a mixture thereof, but is not limited thereto.

The resin may be a phenolic resin including at least one aromatic moiety of Group 1.

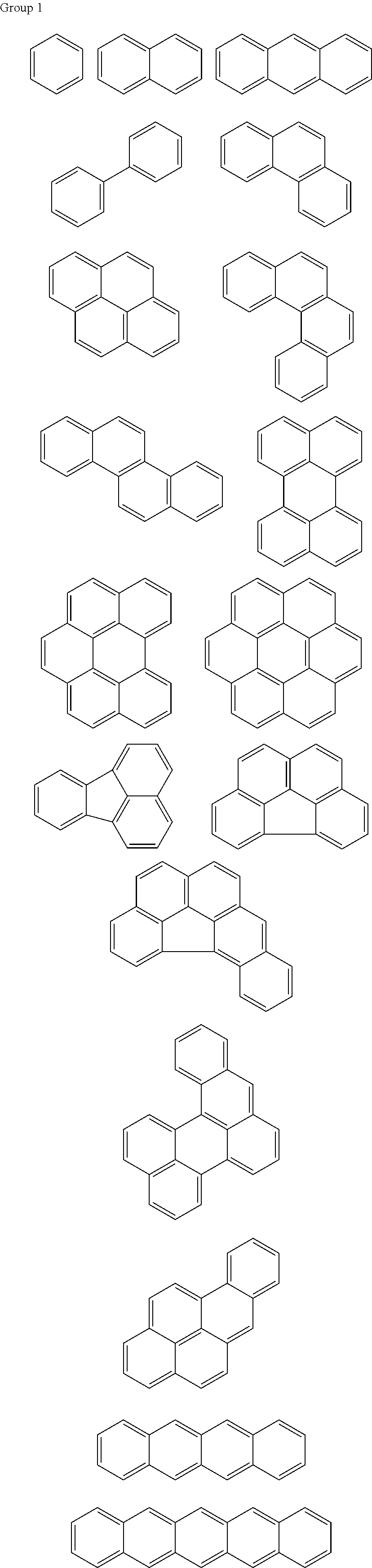

The resin may have a weight average molecular weight of about 500 to about 20,000.

The resin may be included in an amount of about 0.1 wt % to about 50 wt % based on a total amount of the semiconductor photoresist composition.

If the resin is included in the above content range, it may have excellent etch resistance and heat resistance.

In embodiments, the semiconductor photoresist composition may consist of the aforementioned organometallic compound, solvent, and resin.

The semiconductor photoresist composition may further include additives as needed. Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. The crosslinking agent may have at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, and/or methoxymethylated thiourea, and/or the like.

The leveling agent may be used for improving coating flatness during printing and may be any suitable commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl(p-tolyl) amine, methyl diphenyl amine, triphenyl amine, phenylenediamine, naphthylamine, diaminonaphthalene, or a combination thereof.

A use amount of the additives may be controlled depending on suitable or desired properties.

In embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as vinyltrimethoxysilane, vinyl triethoxysilane, vinyl trichlorosilane, vinyl tris(p-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but is not limited thereto.

Subsequently, a substrate 100 having the photoresist film 106 is subjected to a first baking process. The first baking process may be performed at about 80° C. to about 120° C.

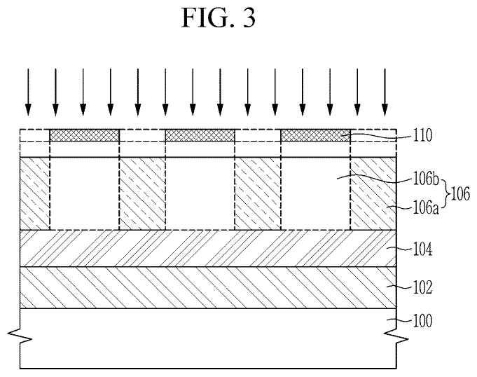

Referring to FIG. 3, the photoresist film 106 may be selectively exposed using a patterned mask 110.

For example, the exposure may use an activation radiation including light having a high energy wavelength such as EUV (extreme ultraviolet; a wavelength of about 13.5 nm), an E-Beam (an electron beam), and/or the like as well as a wavelength such as an i-line (a wavelength of about 365 nm), a KrF excimer laser (a wavelength of about 248 nm), an ArF excimer laser (a wavelength of about 193 nm), and/or the like.

For example, light for the exposure according to an embodiment may have a short wavelength range from about 5 nm to about 150 nm and a high energy wavelength, for example, EUV (Extreme UltraViolet; a wavelength of about 13.5 nm), an E-Beam (an electron beam), and/or the like.

An exposed region 106a of the photoresist film 106 has a different solubility from an unexposed region 106b of the photoresist film 106 by forming a polymer by a crosslinking reaction such as a condensation reaction between organometallic compounds.

Subsequently, the substrate 100 is subjected to a second baking process. The second baking process may be performed at a temperature of about 90° C. to about 200° C. The exposed region 106a of the photoresist film 106 becomes easily indissoluble with respect to a developing solution due to the second baking process.

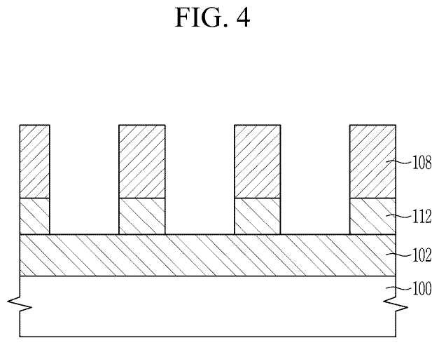

In FIG. 4, the unexposed region 106b of the photoresist film is dissolved and removed using the developing solution to form a photoresist pattern 108. In embodiments, the unexposed region 106b of the photoresist film is dissolved and removed by using an organic solvent such as 2-heptanone and/or the like to complete the photoresist pattern 108 corresponding to the negative tone image.

As described above, a developing solution used in a method of forming patterns according to an embodiment may be an organic solvent. The organic solvent used in the method of forming patterns according to an embodiment may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to an embodiment is not necessarily limited to the negative tone image but may be formed to have a positive tone image. In embodiments, a developing agent used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (Extreme UltraViolet; a wavelength of about 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In embodiments, the photoresist pattern 108 may have a pitch of having a half-pitch of less than or equal to about 50 nm, for example, less than or equal to about 40 nm, for example, less than or equal to about 30 nm, for example, less than or equal to about 20 nm, or for example less than or equal to about 15 nm and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic film pattern 112 is formed. The organic film pattern 112 also may have a width corresponding to that of the photoresist pattern 108.

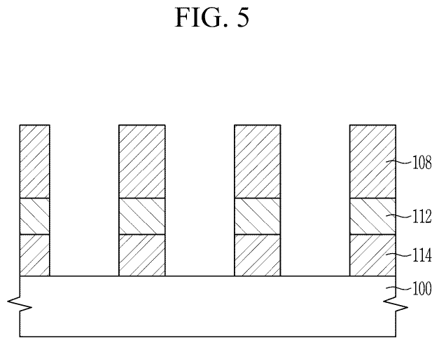

Referring to FIG. 5, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF₃, CF₄, Cl₂, BCl₃, and/or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of 5 nm to 100 nm which 1 is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or, for example, a width of less than or equal to about 20 nm, like that of the photoresist pattern 108.

According to some embodiments, a photoresist film used in the aforementioned method of forming patterns is provided.

The photoresist film according to some embodiments may include a compound represented by (R¹Sn)ₓO_{y}(OAR²)_{z} (wherein x, y, and z are each independently 0.1 to 0.9, x+y+z=1, A is a single bond (e.g., a single covalent bond) or C═O, R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and Ra is a substituted or unsubstituted C1 to C20 alkyl group), and R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) before or after exposure.

The photoresist film may have a thickness of about 5 nm to about 100 nm.

Hereinafter, embodiments of the present disclosure will be described in more detail through examples of the preparation of the aforementioned semiconductor photoresist composition. However, the technical features of the present disclosure are not limited by the following examples.

### Synthesis of Organometallic Compound

### Synthesis Example 1

In a 250 ml 2-necked round-bottomed flask, 40.7 g of t-butylSnPh₃ and 300 g of propionic acid were heated under reflux for 24 hours.

The unreacted propionic acid was removed therefrom under a reduced pressure to obtain a compound represented by Chemical Formula 2.

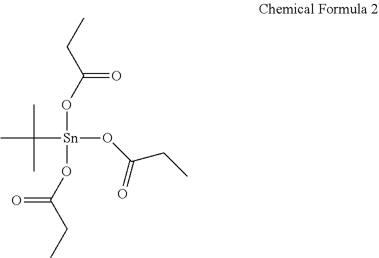 [SMILES: CCC(=O)[O][Sn]([O]C(=O)CC)([O]C(=O)CC)[C](C)(C)C]

### Synthesis Example 2

A compound represented by Chemical Formula 3 was obtained in the same manner as in Synthesis Example 1 except that butyric acid was applied instead of the propionic acid.

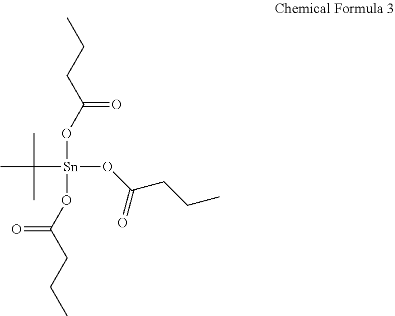 [SMILES: CCCC(=O)[O][Sn]([O]C(=O)CCC)([O]C(=O)CCC)[C](C)(C)C]

### Synthesis Example 3

A compound represented by Chemical Formula 4 was obtained in the same manner as in Synthesis Example 1 except that t-amylSnPh₃ was applied instead of the t-butylSnPh₃.

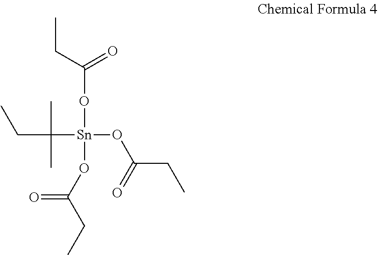 [SMILES: CCC(=O)[O][Sn]([O]C(=O)CC)([O]C(=O)CC)[C](C)(C)CC]

### Synthesis Example 4

A compound represented by Chemical Formula 5 was obtained in the same manner as in Synthesis Example 1 except that butyric acid instead of the propionic acid and t-amylSnPh₃ instead of the t-butylSnPh₃ were applied.

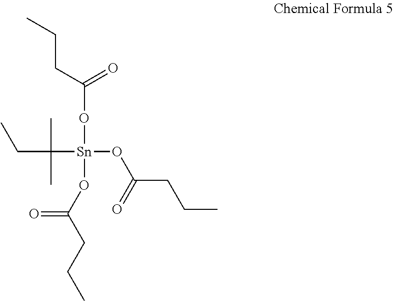 [SMILES: CCCC(=O)[O][Sn]([O]C(=O)CCC)([O]C(=O)CCC)[C](C)(C)CC]

### Synthesis Example 5

30 ml of anhydrous pentane was applied to 10 g of t-AmylSnCl₃ and then, maintained at 0° C., and 7.4 g of diethyl amine and 6.1 g of ethanol were added thereto and then, stirred at room temperature for 1 hour. After a reaction was completed, the resultant was filtered, concentrated, and vacuum-dried to obtain a compound represented by Chemical Formula 6.

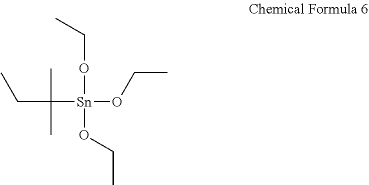

### Preparation of Semiconductor Photoresist Composition

### Examples 1 to 14 and Comparative Examples 1 to 9

The compounds represented by Chemical Formulas 2 to 6 according to Synthesis Examples 1 to 5 and the compounds represented by Chemical Formulas 7 to 9 (obtained from Sigma-Aldrich Corporation) were respectively dissolved at a concentration of 3 wt % in each composition shown in Table 1 and then, filtered with a 0.1 μm PTFE (polytetrafluoroethylene) syringe filter to prepare semiconductor photoresist compositions.

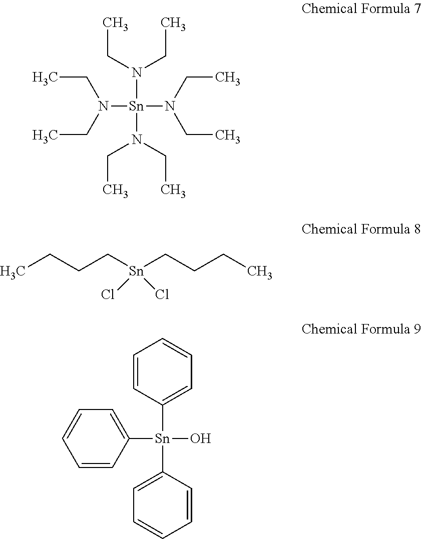

TABLE 1

| | Organometallic compound | Solvent |
|---|---|---|
| Example 1 | Chemical Formula 2 | PGMEA |
| Example 2 | Chemical Formula 2 | PGME |
| Example 3 | Chemical Formula 2 | MIBC |
| Example 4 | Chemical Formula 3 | PGMEA |
| Example 5 | Chemical Formula 3 | PGME |
| Example 6 | Chemical Formula 3 | MIBC |
| Example 7 | Chemical Formula 4 | PGMEA |
| Example 8 | Chemical Formula 4 | PGME |
| Example 9 | Chemical Formula 4 | MIBC |
| Example 10 | Chemical Formula 5 | PGMEA |
| Example 11 | Chemical Formula 5 | PGME |
| Example 12 | Chemical Formula 5 | MIBC |
| Example 13 | Chemical Formula 6 | PGME |
| Example 14 | Chemical Formula 6 | MIBC |
| Comparative Example 1 | Chemical Formula 7 | PGMEA |
| Comparative Example 2 | Chemical Formula 7 | PGME |
| Comparative Example 3 | Chemical Formula 7 | MIBC |
| Comparative Example 4 | Chemical Formula 8 | PGMEA |
| Comparative Example 5 | Chemical Formula 8 | PGME |
| Comparative Example 6 | Chemical Formula 8 | MIBC |
| Comparative Example 7 | Chemical Formula 9 | PGMEA |
| Comparative Example 8 | Chemical Formula 9 | PGME |
| Comparative Example 9 | Chemical Formula 9 | MIBC |

* PGMEA: Propylene glycol monomethyl ether acetate
* PGME: Propylene glycol methyl ether
* MIBC: 4-Methyl-2-pentanol

### Evaluation: Sensitivity, LER, And Limiting Resolution

Each of the compositions for a photoresist was spin-coated on a 200 mm circular silicon wafer at 1500 rpm for 30 seconds, baked at 110° C. for 60 seconds, and allowed to stand at room temperature for 30 seconds. Subsequently, the wafer was exposed by splitting an exposure dose with an EUV light source (Lawrence Berkeley National Laboratory Micro Exposure Tool) to pattern it into various L/S (1/1) sizes and thus obtain a photoresist thin film. After the exposure, the film was fired at 170° C. for 60 seconds and subsequently, developed with a PGMEA solvent. Finally, the film was fired at 150° C. for 60 seconds and then, analyzed through SEM (scanning electron microscopy).

### Sensitivity Evaluation Criteria

A: less than 100 mJ/cm²
B: greater than or equal to 100 mJ/cm²

### LER Evaluation Criteria

∘: less than or equal to 2 nm
Δ: greater than 2 nm and less than or equal to 5 nm
X: greater than 5 nm

### Limited Resolution Evaluation Criteria

A: less than CD 10 nm
B: greater than or equal to CD 10 nm

TABLE 2

| | Sensitivity | LER | Limiting |
|---|---|---|---|
| | (@ CD 14 nm) | (@ CD 14 nm) | resolution |
| Example 1 | A | ∘ | A |
| Example 2 | A | ∘ | A |
| Example 3 | A | ∘ | A |
| Example 4 | A | ∘ | A |
| Example 5 | A | ∘ | A |
| Example 6 | A | ∘ | A |
| Example 7 | A | ∘ | A |
| Example 8 | A | ∘ | A |
| Example 9 | A | ∘ | A |
| Example 10 | A | ∘ | A |
| Example 11 | A | ∘ | A |
| Example 12 | A | ∘ | A |
| Example 13 | A | ∘ | A |
| Example 14 | A | Δ | A |
| Comparative | A | Δ | B |
| Example 1 | | | |
| Comparative | A | Δ | B |
| Example 2 | | | |
| Comparative | A | Δ | B |
| Example 3 | | | |
| Comparative | B | X | B |
| Example 4 | | | |
| Comparative | B | X | B |
| Example 5 | | | |
| Comparative | B | X | B |
| Example 6 | | | |
| Comparative | B | X | B |
| Example 7 | | | |
| Comparative | B | X | B |
| Example 8 | | | |
| Comparative | B | X | B |
| Example 9 | | | |

Referring to the results of Table 2, patterns formed by using the photoresist compositions for a semiconductor according to Examples 1 to 14 exhibited excellent sensitivity, LER, and resolution characteristics, compared to patterns formed by using the photoresist compositions for a semiconductor according to Comparative Examples 1 to 9.

Hereinbefore, certain embodiments of the present disclosure have been described and illustrated, however, it is apparent to a person with ordinary skill in the art that the present disclosure is not limited to the embodiment as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the appended claims of the present disclosure, and equivalents thereof.

Description of Symbols

| | |
|---|---|
| 100: substrate | 102: thin film |
| 104: resist underlayer | 106: photoresist film |
| 106a: exposed region | 106b: unexposed region |
| 108: photoresist pattern | 112: organic film pattern |
| 110: patterned mask | 114: thin film pattern |

What is claimed is:

1. A method of forming patterns, comprising:
coating a semiconductor photoresist composition comprising an organic tin compound on a substrate;
drying and heating to form a photoresist film; and
exposing and developing the photoresist film,
wherein the organic tin compound has at least one organic ligand comprising a Sn—C bond and at least one organic carbonyloxy group, and
the photoresist film comprises a compound represented by (R¹Sn)ₓO_{y}(OAR²)_{z} (wherein x, y, and z are each independently 0.1 to 0.9, x+y+z=1, A is a single bond or C═O, R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and Ra is a substituted or unsubstituted C1 to C20 alkyl group), and R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof) before or after exposure.

2. The method of forming patterns as claimed in claim 1, wherein:
the photoresist film comprises an Sn—OAR² bond, an Sn—O—Sn bond, and an Sn—C bond.

3. The method of forming patterns as claimed in claim 1, wherein:
before exposure, a content of the compound represented by (R¹Sn)ₓO_{y}(OAR²)_{z} included in the photoresist film is about 5 to about 95 wt % based on 100 wt % of the semiconductor photoresist composition.

4. The method of forming patterns as claimed in claim 1, wherein:
after exposure and development, a content of the compound represented by (R¹Sn)ₓO_{y}(OAR²)_{z} included in the photoresist film is about 5 to about 95 wt % based on 100 wt % of the semiconductor photoresist composition.

5. The method of forming patterns as claimed in claim 1, wherein:
coating a semiconductor photoresist composition comprising an organic tin compound on a substrate is performed by one method selected from:
a deposition method selected from chemical vapor deposition (CVD) and physical vapor deposition (PVD), and
a coating method selected from spin coating, slit coating, and inkjet printing.

6. The method of forming patterns as claimed in claim 1, wherein:
the exposing of the photoresist film is performed using light having a wavelength of about 5 nm to about 150 nm.

7. The method of forming patterns as claimed in claim 1, wherein:
R¹ is a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, an ethoxy group, a propoxy group, or a combination thereof, and
R² is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

8. The method of forming patterns as claimed in claim 1, wherein:
R¹ is a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof, and
R² is hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

9. The method of forming patterns as claimed in claim 1, wherein:
the semiconductor photoresist composition further comprises an additive of a surfactant, a crosslinking agent, a leveling agent, an organic acid, a quencher, or a combination thereof.

10. A photoresist film comprising a compound represented by (R¹Sn)ₓO_{y}(OAR²)_{z} (wherein x, y, and z are each independently 0.1 to 0.9, x+y+z=1, A is a single bond or C═O, R¹ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C6 to C30 arylalkyl group, and L^{a}-O—R^{a} (wherein L^{a} is a substituted or unsubstituted C1 to C20 alkylene group and Ra is a substituted or unsubstituted C1 to C20 alkyl group), and R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof).

11. The photoresist film as claimed in claim 10, wherein:
the photoresist film has a thickness of about 5 nm to about 100 nm.
